(19) United States
(12) Patent Application Publication
(10) Pub. No.: US 2009/0039956 A1
(43) Pub. Date: Feb. 12, 2009

(54) AMPLIFIER CIRCUITS, IMAGER, SYSTEM AND METHOD OF OPERATION

(75) Inventor: Yaowu Mo, Arcadia, CA (US)

Correspondence Address: TRASK BRITT, P.C./ MICRON TECHNOLOGY, P.O. BOX 2550, SALT LAKE CITY, UT, 84110, US

(73) Assignee: MICRON TECHNOLOGY, INC., Boise, ID (US)

(21) Appl. No.: 11/835,026

(22) Filed: Aug. 7, 2007

(51) Int. Cl. H03F 1/02

(52) U.S. Cl. 330/9

(57) ABSTRACT

Systems, imagers, amplifiers and methods for use in operating a multi-channel amplifier. The multi-channel amplifier operates in a plurality of channels. A respective plurality of non-overlapping clock signals is generated for connecting a shared operational amplifier into respective portions of a switched-capacitor amplifier circuit. Between assertions of the non-overlapping clock signals, the shared operational amplifier is substantially electrically isolated from the switched-capacitor amplifier circuit to remove current leakage paths. Inputs and outputs of the shared operational amplifier are shorted to remove residual charge from the circuit.

### FIELD OF THE INVENTION

Embodiments of the present invention relate to imager devices and, more particularly, to amplifier circuits for multiple channel readout architectures, devices and systems incorporating same, and methods of operation

### BACKGROUND

A CMOS imager circuit includes an array of pixel cells, with each one of the cells including a photosensor, for example, a photogate, photoconductor or a photodiode overlying a substrate for accumulating photo-generated charge in the underlying portion of the substrate. Each pixel cell has a readout circuit that includes at least an output field effect transistor formed in the substrate, a charge storage region formed on the substrate connected to the gate of an output transistor and amplification and analog-to-digital conversion circuitry. The charge storage region may be constructed as a floating diffusion region. Each pixel may include at least one electronic device such as a transistor for transferring charge from the photosensor to the storage region and one device, also typically a transistor, for resetting the storage region to a predetermined charge level prior to charge transference.

In a CMOS imager, the active elements of a pixel cell perform the necessary functions of: (1) photon to charge conversion; (2) accumulation of image charge; (3) resetting the storage region to a known state before the transfer of charge, (4) transfer of charge to the storage region accompanied by charge amplification; (5) selection of a pixel for readout; and (6) output and amplification of a signal representing pixel charge. Photo charge may be amplified when it moves from the initial charge accumulation region to the storage region. The charge at the storage region is typically converted to a pixel output voltage by a source follower output transistor. CMOS imagers of the type discussed above are generally known as discussed, for example, in U.S. Pat. No. 6,140,630, U.S. Pat. No. 6,376,868. U.S. Pat. No. 6,310,366, U.S. Pat. No. 6,326,652, U.S. Pat. No. 6.204,524 and U.S. Pat. No. 6,333,205, assigned to Micron Technology, Inc., the disclosure of each of which is hereby incorporated by reference in its entirety.

There is a desire to increase the speed of a data readout process including the amplification and analog-to-digital conversion process in many applications such as e.g., imagers. As such, various imagers use pipelined readout circuits, which typically operate faster than non-pipelined readout circuits. A conventional pipelined readout circuit requires one operational amplifier for each stage in the pipeline. The majority of the power of the pipelined readout circuit is consumed by operational amplifiers. Therefore, minimizing the power consumption of the operational amplifiers is significant to the design of low power pipelined readout architectures.

Readout circuits may also be pipelined by using multiple readout channels. For example, imagers may include multiple readout channels where one channel processes a specific set of pixel signals and at least one other channel processes another set of pixel signals. In multiple channel readout architectures, operational amplifiers may be shared between channels and thereby reduce the overall power consumption. Specifically, the channels switch the shared operational amplifier into or out of the channel based on the operation being performed in that portion of the channel. Thus, a multiple channel readout architecture achieves the benefits of reducing the number of operational amplifiers by sharing an operational amplifier with one channel while the second channel performs operations that do not require the operational amplifier. The operational amplifier is then shared with the second channel while the first channel engages in processing that does not need the operational amplifier.

When a shared operational amplifier in a multi-stage or multi-channel readout architecture is configured as a switched-capacitor amplifier, unnecessary standby current may be wasted through extraneous DC current paths that remain activated when the shared operational amplifier passes through a standby state while switching between alternate stages or channels. Accordingly, there is a need and desire for sharing an operational amplifier between to channels of a signal processing circuit that does not suffer from the needless consumption of standby current during stage or channel transitions or during system standby phases.

### BRIEF DESCRIPTION OF THE SEVERAL VIEWS OF THE DRAWINGS

FIG. 1 illustrates a portion of an imager, in accordance with an embodiment of the present invention.

FIG. 2 illustrates a timing diagram for a readout architecture, in accordance with an embodiment of the present invention.

FIG. 3 illustrates a two-channel readout circuit, in accordance with an embodiment of the present invention.

FIG. 4 illustrates a circuit diagram of a portion of an imager including a multi-channel shared operational amplifier, in accordance with an embodiment of the present invention.

FIG. 5 illustrates waveforms generated by a clock generator for activation of respective portions of a shared operational amplifier, in accordance with an embodiment of the present invention.

FIG. 6 illustrates the multi-channel share operational amplifier, in accordance wit an embodiment of the present invention.

FIG. 7 illustrates an imager, in accordance with an embodiment of the present invention.

FIG. 8 illustrates a system including an imaging device, in accordance with an embodiment of the present invention.

### DETAILED DESCRIPTION OF THE INVENTION

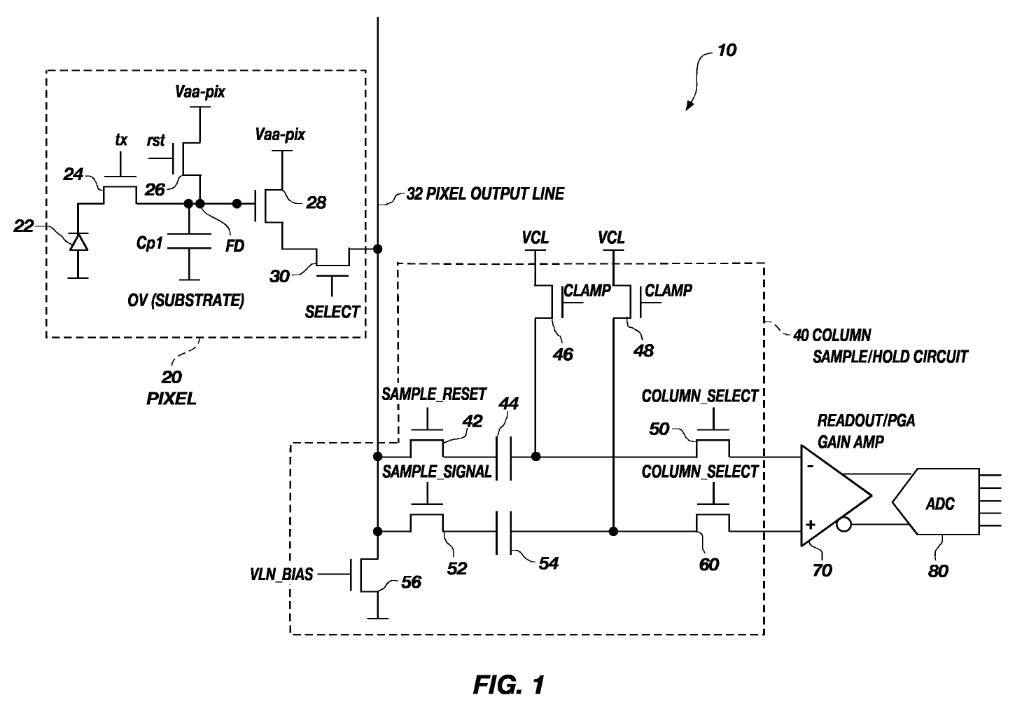

FIG. 1 illustrates a portion of a CMOS imager, in accordance with an embodiment of the present invention. The illustrated imager 10 includes a pixel 20, one of many that are in a pixel array (not shown), connected to a column sample-and-hold circuit 40 by a pixel output line 32. The imager 10 also includes a readout amplifier (e.g., programmable gain amplifier (PGA)) 70 and an analog-to-digital converter (ADC) 80.

The illustrated pixel 20 includes a photosensor 22 (e.g., a pinned photodiode, photogate, etc.), transfer transistor 24, floating diffusion region FD, reset transistor 26, source follower transistor 28 and row select transistor 30. FIG. 1 also illustrates parasitic capacitance Cp1 associated with the floating diffusion region FD and the substrate. The photosensor 22 is connected to the floating diffusion region FD by the transfer transistor 24 when the transfer transistor 24 is activated by a transfer control signal TX. The reset transistor 26 is connected between the floating diffusion region FD and an array pixel supply voltage Vaa-pix. A reset control signal RST is used to activate the reset transistor 26, which resets the floating diffusion region FD.

The source follower transistor 28 has its gate connected to the floating diffusion region D and is connected between the array pixel supply voltage Vaa-pix and the row select transistor 30. The source follower transistor 28 converts the stored charge at the floating diffusion region FD into an electrical output voltage signal. The row select transistor 30 is controllable by a row select signal SELECT for selectively connecting the source follower transistor 28 and its output voltage signal to the pixel output line 32.

The column sample-and-hold circuit 40 includes a bias transistor 56, controlled by a control voltage Vln_bias, which is used to bias the pixel output line 32. The pixel output line 32 is also connected to a first capacitor 44 thru a sample-and-hold reset signal switch 42. The sample-and-hold reset signal switch 42 is controlled by the sample-and-hold reset control signal SAMPLE_RESET. The pixel output line 32 is also connected to a second capacitor 54 thru a sample-and-hold pixel signal switch 52. The sample-and-hold pixel signal switch 52 is controlled by the sample-and-hold pixel control signal SAMPLE_SIGNAL. The switches 42, 52 are typically MOSFET transistors.

A second terminal of the first capacitor 4 is connected to the readout amplifier 70 via a first column select switch 50, which is controlled by a column select signal COLUMN_SELECT. The second terminal of the first capacitor 44 is also connected to a clamping voltage VCL via a first clamping switch 46. Similarly, the second terminal of the second capacitor 54 is connected to the readout amplifier 70 by a second column select switch 60, which is controlled by the column select signal COLUMN_SELECT. The second terminal of the second capacitor 54 is also connected to the clamping voltage VCL by a second clamping switch 48.

The clamping switches 46, 48 are controlled by a clamping control signal CLAMP. As is known in the art, he clamping voltage VCL is used to place a charge on the two capacitors 4, 54 when it is desired to store the reset and pixel signals, respectively (when the appropriate sample-and-hold control signals SAMPLE_RESET, SAMPLE_SIGNAL are also generated).

In operation, the row select signal SELECT is driven high, which activates the row select transistor 30. When activated, the row select transistor 30 connects the source follower transistor 28 to the pixel output line 32. The clamping control signal CLAMP is then driven high to activate the clamping switches 46, 48, allowing the clamping voltage VCL to be applied to the second terminal of the sample-and-hold capacitors 44, 54. The reset signal RST is then pulsed to activate the reset transistor 26, which resets the floating diffusion region FD. The signal on the floating diffusion region FD is then sampled when the sample-and-hold reset control signal SAMPLE_RESET is pulsed. At this point, the first capacitor 44 stores the pixel reset signal Vᵣₛₜ.

Immediately afterwards, the transfer transistor control signal TX is pulsed, causing charge from the photosensor 22 to be transferred to the floating, diffusion region FD. The signal on the floating diffusion region FD is sampled when the sample-and-hold pixel control signal SAMPLE_SIGNAL is pulsed. At this point, the second capacitor 54 stores a pixel image signal V_{sig}. A differential signal (Vᵣₛₜ—V_{sig}) is produced by the readout amplifier 70. The differential signal is digitized by the analog-to-digital converter 80. The analog-to-digital convener 80 supplies the digitized pixel signals to an image processor (not shown), which forms a digital image output.

As stated, there is a desire to increase the speed of the readout process including the amplification and analog-to-digital conversion process in many applications such as e.g., imagers. As such, many applications use pipelined readout architectures which require one operational amplifier for each stage in the pipeline. As stated, the majority of the power of the pipelined readout architecture is consumed by operational amplifiers. Therefore, minimizing the power consumption of the operational amplifiers results in a low power pipelined readout architecture.

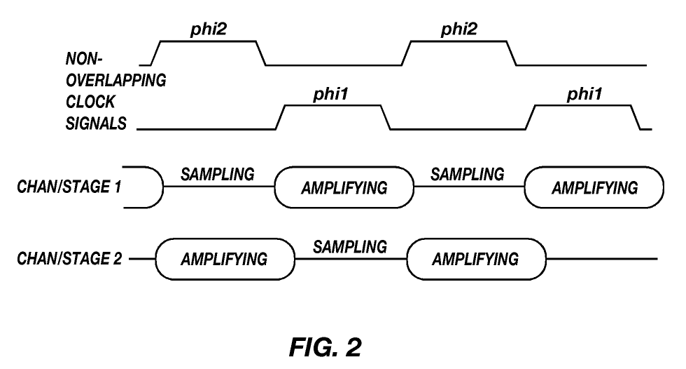

FIG. 2 illustrates the timing diagram for two channels or stages CHAN/STAGE 1, CHAN/STAGE 2 of a pipelined readout architecture. Non-overlapping clock signals PHI_1, PHI_2 are used to control the switching circuitry contained within each channel or stage CHAN/STAGE 1, CHAN/STAGE 2 to configure how the sampling and feedback of the shared operational amplifiers are connected.

When the second clock signal PHI_2 is asserted (i.e., has a high level) as can be seen in FIG. 2, the first channel or stage CHAN/STAGE 1 undergoes a sampling operation while the second channel or stage CHAN/STAGE 2 undergoes an amplifying operation. When the first clock signal PHI_1 is asserted (i.e., has a high level) as can be seen in FIG. 2, the first channel or stage CHAN/STAGE 1 undergoes the amplifying operation while the second channel or stage CHAN/STAGE 2 undergoes the sampling operation.

It can be seen during the sampling operations for a dedicated or non-shared operational amplifier architecture, the operational amplifiers perform no useful function; they just consume power. This occurs because the operational amplifiers are placed into an open-loop configuration with their inputs and outputs connected to known voltage levels. To avoid wasting power during every sampling operation, channels or stages may share one operational amplifier between two adjacent channels or stages CHAN/STAGE 1, CHAN/STAGE 2. By sharing an operational amplifier between two adjacent channels or stages CHAN/STAGE 1, CHAN/STAGE 2, the power consumption of the pipelined stages can be reduced by half.

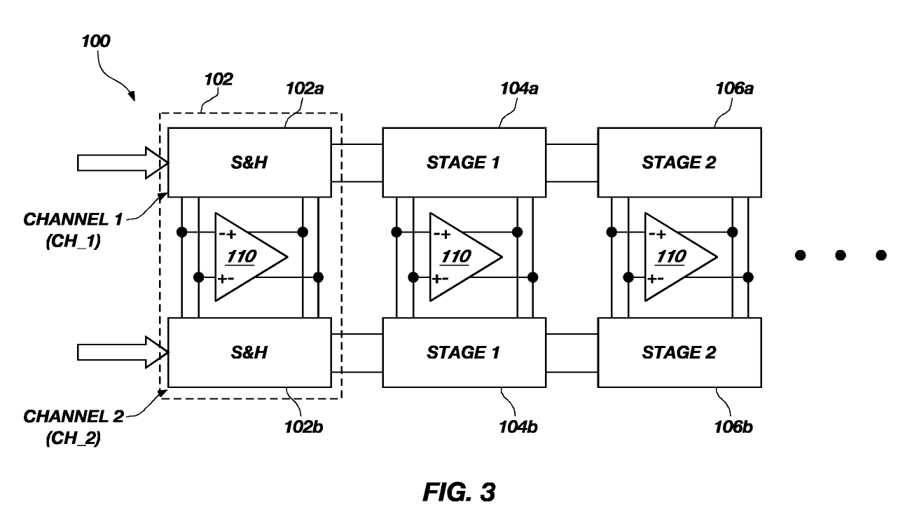

As stated, readout circuitry can be divided into multiple channels. For example, imagers often include multiple readout channels where one channel processes a specific set of pixel signals and at least one other channel processes another set of pixel signals. FIG. 3 illustrates a two channel readout circuit 100 designed to provide gain to analog input signals and convert the signals into digital signals. As shown in FIG. 3, the two channel readout circuit 100 includes a readout amplifier 102 including a first channel CHANNEL 1 comprising a gain circuit 102ₐ and multiple analog-to-digital pipeline stages 104ₐ, 106ₐ. Similarly, the second channel CHANNEL 2 comprises a gain circuit 102_{b} and multiple analog-to-digital pipeline stages 104_{b}, 106_{b}. The gain circuits 102ₐ, 102_{b} share an operational amplifier 110. The analog-to-digital pipeline stages 104ₐ, 104_{b} share an operational amplifier 110 as do the other analog-to-digital pipeline stages 106ₐ, 106_{b}.

The readout circuit includes two channels channel 1 (CH1) and channel 2 (CH2) which share the operational amplifiers 110 according to the timing described above with reference to FIG. 2. That is, the channels switch the shared amplifier 110 into or out of CHANNEL 1 or CHANNEL 2 based on the operation being performed in that stage or portion of the channel. Thus, the readout circuit 100 achieves the benefits of reducing the number of operational amplifiers by sharing an operational amplifier between channels at each stage of the readout process.

As stated, when a shared operational amplifier 110 in a multi-stage or multi-channel readout architecture is configured as a switched-capacitor amplifier, unnecessary standby current may be wasted through extraneous DC current paths that remain activated when the shared operational amplifier passes through a standby state while switching between alternate stages or channels. The readout circuit 100 disclosed herein does not suffer from the needless consumption of standby current during stage or channel transitions as does prior art configurations.

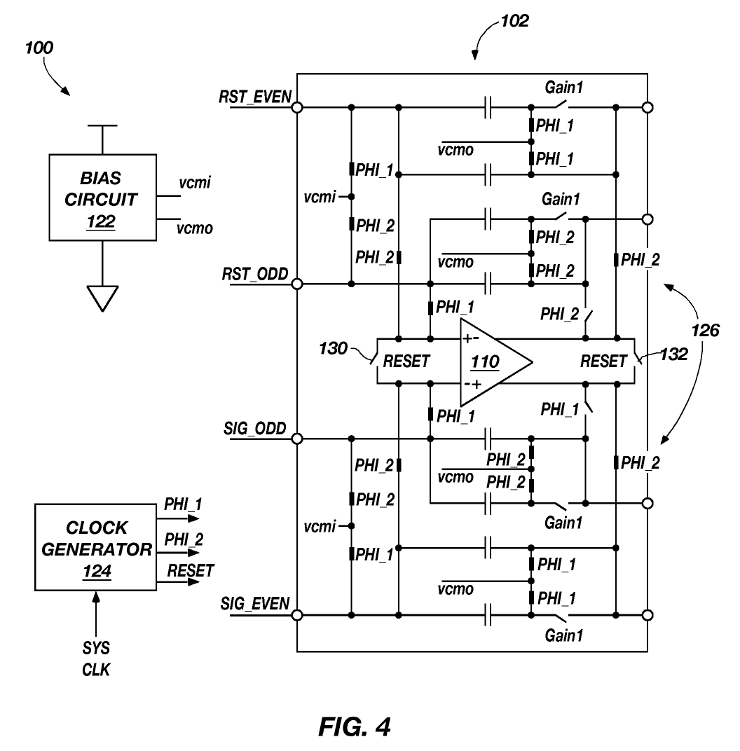

FIG. 4 illustrates a circuit diagram of a portion of an imager 10 (FIG. 1) including a two channel readout circuit 100 including a multi-channel readout amplifier 102, in accordance with an embodiment of the present invention. The multi-channel readout amplifier 102 is configured to couple the operational amplifier 110 between a first (e.g., even) channel and a second (e.g., odd) channel in the two channel readout circuit 100. The imager further includes support circuitry such as a bias circuit 122 and a clock generator 124. Bias circuit 122 generates bias voltages such as input common mode voltage (vcmi) and output common mode voltage (vcmo). Additionally, voltages vcmi and vcmo may optionally be the same bias voltage.

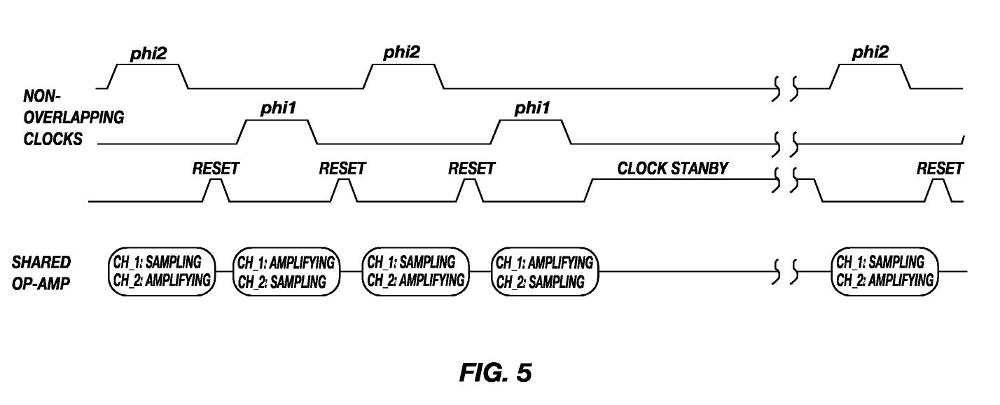

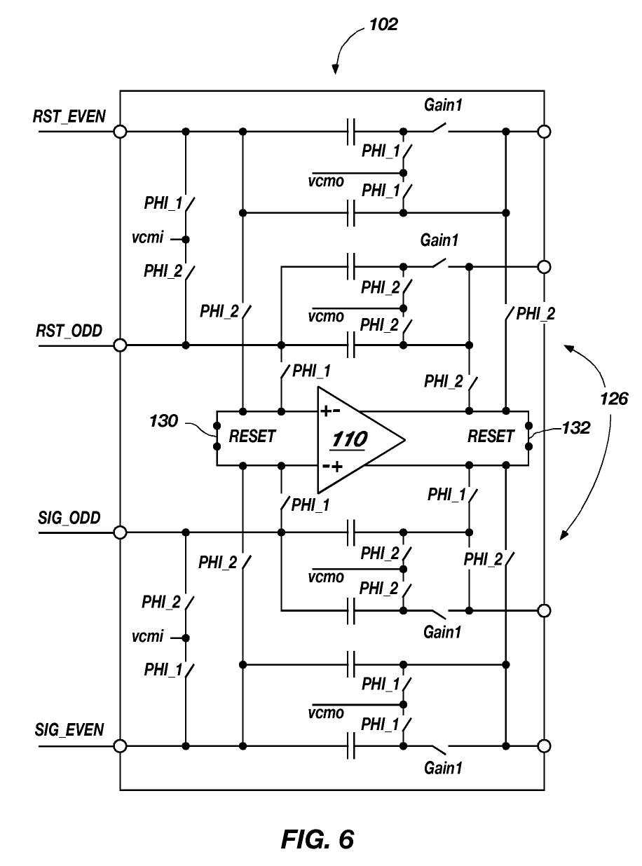

FIGS. 5 and 6 illustrate an improved clock standby configuration for the readout amplifier 102 by setting the switches of the multi-channel switched-capacitor circuit 126 into short-reset mode wherein the inputs of the shared operational amplifier 110 are shorted together and the outputs of the shared operational amplifier 110 are shorted together with all of the internal switches of the multi-channel switched-capacitor circuit 126 being opened. The clock standby phase is often used in the blanking, or row readout interval of the image sensors, to minimize the cross-talk between the row readout and serial readout circuits, and to reduce noise coupling from the clock driver (not shown).

Due to the substantial circuitry associated with a readout circuit, various ground pats tend to exist that create DC current paths from the shared operational amplifier 110 to ground potential during inactive or standby phases of the operational amplifier 110. Because of the various design parameters for other readout circuit components, such as the ADC 80 (FIG. 1), there is motivation to prevent or at least substantially reduce the leakage paths available to the standby current of the shared operational amplifier 110. Various conventional clock standby configurations merely stop the clocks with one of the channels set to an amplifying mode and the other channel set to the sampling mode. Such a configuration results in a standby current leakage path for the shared operational amplifier 110. Furthermore, when one of the channels is in amplifying mode during the clock standby phase, amplification of noise or other signals generate crosstalk on, for example, the long video line or otherwise injects noise into substrate resulting in common-mode voltage disturbances.

FIG. 5 illustrates a CLOCK STANDBY phase wherein the clock signals PHI_1 and PHI_2 are deasserted and the RESET signal is asserted. Such a signal configuration results in the inputs of the shared operational amplifier 110 being shorted together and the outputs of the shared operational amplifier 110 being shorted together with all of the internal switches of the multi-channel switched-capacitor circuit 126 being opened. Such a CLOCK STANDBY phase configuration results in nominal DC current leakage paths from the shared operational amplifier 110 in the readout circuitry. Furthermore, during the CLOCK STANDBY phase described herein, the shared operational amplifier 110 remains powered during the CLOCK STANDBY phase to retain the correct common-mode voltage without requiring time-consuming recovery time when the common-mode voltage is redetermined following power-down of the operational amplifier in conventional clock standby phases.

FIG. 5 illustrates the waveforms generated by clock generator 124 for activation of respective portions of the multi-channel readout amplifier 102. The multi-channel readout amplifier 102 is configured as a switched-capacitor amplifier and includes a shared operational amplifier 110 and a multi-channel switched-capacitor circuit 126. The multi-channel switched-capacitor circuit 126 is configured, in the present embodiment, to support even and odd channels as illustrated with respect to FIG. 3 and includes the channel 1 (CH_1) and channel 2 (CH_2) gain circuits 102ₐ, 102_{b} of FIG. 3. The multi-channel switched-capacitor circuit 126 includes a plurality of capacitors and switches that are configured into feedback arrangements for generating gain in alternating even and odd channels. The various feedback configurations are responsive to the clock signals, PHI_1 and PHI_2, generated by clock generator 204.

The multi-channel readout amplifier 102 further includes switches 130 and 132 respectively coupled between the inputs and outputs of shared operational amplifier 110. As is described below, when the switch 130 is closed in response to the SET signal according to the timing illustrated in FIG. 5, a discharge path between inputs of the shared operational amplifier 110 is created. This discharge path will discharge any parasitic capacitance seen at the inputs of the shared operational amplifier 110, which substantially mitigates any memory effect or residual charge contamination between channels. Similarly, when the switch 132 is closed also in response to the RESET signal according to the timing illustrated in FIG. 5, a discharge path between the outputs of the shared operational amplifier 110 is also created. This discharge path will discharge any parasitic capacitance seen at the outputs of the shared operational amplifier 110, which also substantially mitigates any memory effect or residual charge contamination between channels.

As shown in FIG. 5, when the second clock signal PHI_2 is asserted, the first channel CH 1 undergoes a sampling operation while the second channel CH_2 undergoes an amplifying operation. When the first clock signal PHI_1 is asserted, the first channel CH_1 undergoes an amplifying operation while the second channel CH_2 undergoes a sampling operation. The various switches are respectively closed or activated with the corresponding clock signal PHI_1 or PHI_2 as illustrated in FIG. 4.

As further illustrated in FIG. 5, during the time after the first clock signal PHI_1 transitions low, but before the second clock signal PHI_2 transitions high, a short reset pulse RESET is asserted. The short reset pulse RESET is also asserted during the time after the second clock signal PHI_2 transitions low, but before the first clock signal PHI_1 transitions high.

FIG. 6 illustrates the multi-channel readout amplifier 102 in a reset configuration in response to the assertion of the RESET signal, in accordance with an embodiment of the present invention. A clock generator 124 (FIG. 4) de-asserts the first clock signal PHI_1 and the second clock signal PHI_2 causing all of the switches in the multi-channel switched-capacitor circuit 126 to be opened. The clock generator 124 asserts the RESET signal causing switches 130 and 132 to be closed. As stated, when the switches 130, 132 are closed, respective discharge paths between the shared operational amplifier 110 inputs and outputs are created. These discharge paths discharge any parasitic capacitance seen at the shared operational amplifier 110 inputs and outputs. White the clock generator 124 generates clock signals PHI_1 PHI_2 and RESET for alternating the operational amplifier 110 between even and odd channels, the clock generator 124 may also generate a CLOCK STANDBY phase by maintaining the assertion of the RESET signal as also illustrated in FIG. 5.

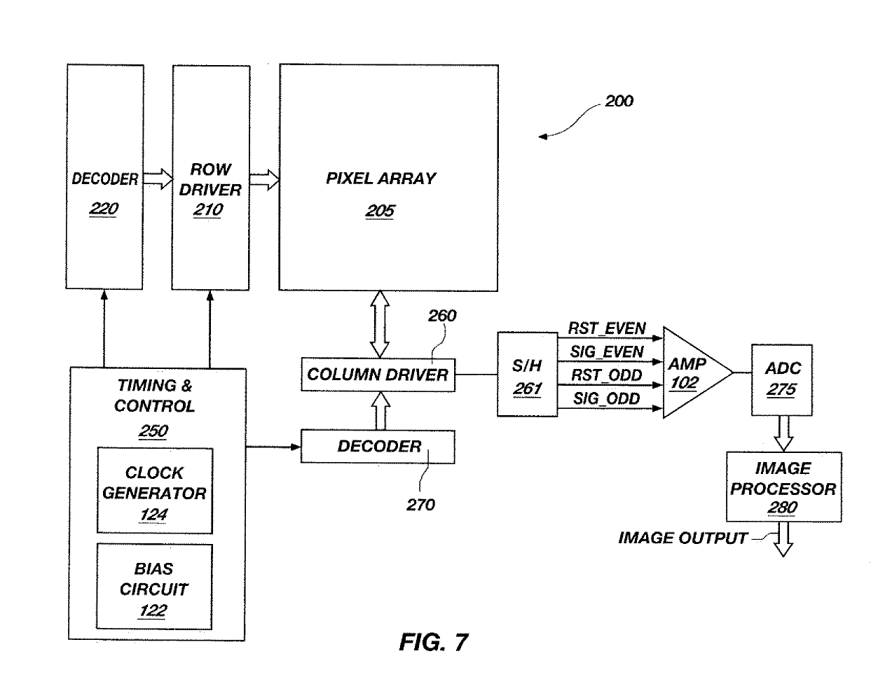

FIG. 7 illustrates an imager 200 that may utilize the readout amplifier in a shared channel configuration, in accordance with an embodiment of the present invention. The imager 200 has a pixel array 205 comprising rows and columns of pixels. Row lines are selectively activated by a row driver 210 in response to row address decoder 220. A column driver 260 and column address decoder 270 are also included in the imager 200. The imager 200 is operated by the timing and control circuit 250 including clock generator 124 and bias circuit 122. The control circuit 250 also controls the row and column driver circuitry 210, 260.

A sample-and-hold circuit 261 associated with the column driver 260 reads a pixel reset signal Vrst and a pixel image signal Vsig for selected pixels. A differential signal (Vrst−Vsig) is amplified by readout amplifier 102 for each pixel and is digitized by the pipelined analog-to-digital converter 275 of the invention- The analog-to-digital converter 275 supplies the digitized pixel signals to an image processor 280, which forms a digital image. Alternatively, the sample-and-hold circuit 261 and the analog-to-digital converter (ADC) 275 may be connected in a shared two channel configuration such as the configuration Illustrated above. Each channel would be responsible for a different set of pixel signals (e.g., one channel can process even pixel signals, while the other channel processes odd pixel signals).

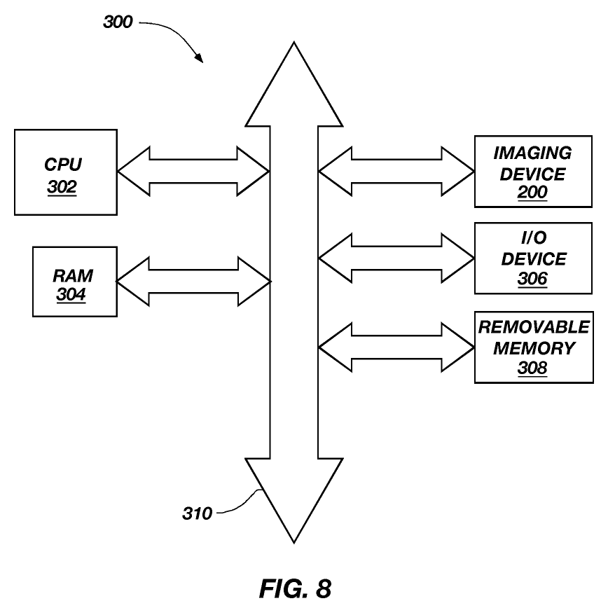

FIG. 8 shows a system 300, a conventional processor system modified to include an imaging device 20. The processor system 300 is exemplary of a system having digital circuits that could include image sensor devices. Without being limiting, such a system could include a computer system, camera system, scanner, machine vision, vehicle navigation, video phone, surveillance system, auto focus system, star tracker system, motion detection system, image stabilization system, and data compression system.

System 300, for example a camera system, generally comprises a central processing unit (CPU) 302, such as a microprocessor, that communicates with an input/output (I/O) device 306 over a bus 310. Imaging device 200 also communicates with the CPU 302 over the bus 310. The processor-based system 300 also includes random access memory (RAM) 30, and can include removable memory 308, such as flash memory, which also communicate with the CPU 302 over the bus 310. The imaging device 200 may be combined with a processor, such as a CPU, digital signal processor, or microprocessor, with or without memory storage on a single integrated circuit or on a different chip than the processor.

Embodiments of systems, imagers, amplifiers and methods for use in operating a multi-channel amplifier have been disclosed. The multi-channel amplifier operates in a plurality of channels. A respective plurality of non-overlapping clock signals is generated for connecting a shared operational amplifier into respective portions of a switched-capacitor amplifier circuit. Between assertion of the non-overlapping clock signals, a reset signal is generated which substantially electrically isolates the shared operational amplifier from all of the portions of the switched-capacitor amplifier circuit. Additionally, the reset signal also shorts inputs signals together and output signals together on the shared operational amplifier.

The multi-channel amplifier includes a shared operational amplifier including a pair of inputs and a pair of outputs for selectively electrically coupling into a plurality of channels. The amplifier further includes a multi-channel switched-capacitor circuit responsive to a respective plurality of non-overlapping clock signals. A shared operational amplifier is electrically connected to a respective portion of a switched-capacitor amplifier circuit corresponding to a respective one of the plurality of channels in response to an asserted one of the plurality of non-overlapping clock signals. A reset signal shorts both the inputs together and shorts the outputs together of the shared operational amplifier between assertions of each of the plurality of non-overlapping clock signals. The reset signal also opens all switches in the multi-channel switched-capacitor circuit.

The processes and devices described above illustrate selected embodiments of methods and devices of many that may be used and produced in accordance with the invention. However, it is not intended that the present invention be limited to the above-described and illustrated embodiments. Any modification, though presently unforeseeable, of the present invention that comes within the scope of the following claims and their legal equivalents is considered part of the present invention.

1. A method of operating a multi-channel readout amplifier, comprising:
generating each of a respective plurality of clock signals;
connecting a shared operational amplifier to a respective portion of a switched-capacitor amplifier circuit corresponding to a respective one of the plurality of channels in response to an asserted one of the plurality of clock signals;
shorting inputs together and shorting outputs together of the shared operational amplifier between deassertion of one of the plurality of clock signals and assertion of a subsequent one of the plurality of clock signals; and
opening all switches in the switched-capacitor amplifier circuit when the inputs and the outputs of the shared operational amplifier are shorted.

2. The method of claim 1, further comprising generating a reset signal for controlling the shorting of the inputs together and the shorting of the outputs together of the shared operational amplifier.

3. The method of claim 2, wherein the plurality of clock signals and the reset signal are non-overlapping.

4. The method of claim 3, wherein generating the reset signal inhibits sampling or amplifying in any of the plurality of channels.

5. The method of claim 4, wherein generating the reset signal further comprises sustaining generation of the reset signal during a clock standby phase.

6. The method of claim 1, wherein connecting the shared operational amplifier to the portion of the switched-capacitor amplifier of the one of the plurality of channels further comprises amplifying through the one of the plurality of channels.

7. The method of claim 6, wherein connecting the shared operational amplifier to the portion of the switched-capacitor amplifier of the one of the plurality of channels further comprises sampling through others of the plurality of channels.

8. A method of operating an amplifier shared by two channels, comprising:
alternatingly electrically coupling the shared operational amplifier into each of the two channels; and
electrically isolating the shared operational amplifier from each of the two channels between transitioning between the two channels.

9. The method of claim 8, further comprising electrically shorting the inputs together and electrically shorting the outputs together of the shared operational amplifier during transitions between the two channels.

10. The method of claim 9, further comprising sustaining the shorting of the inputs and the outputs and the electrically isolating of the shared operational amplifier during a clock standby phase.

11. The method of claim 8, wherein alternatingly electrically coupling further comprises concurrently amplifying through the one of the two channels and sampling through the other one of the two channels.

12. The method of claim 11, further comprising neither amplifying nor sampling either of the two channels when the shared operational amplifier is electrically isolated from each of the two channels.

13. A multi-channel amplifier, comprising:
a shared operational amplifier including a pair of inputs and a pair of outputs for selectively electrically coupling into a plurality of channels; and
a multi-channel switched-capacitor circuit responsive to a respective plurality of non-overlapping clock signals to electrically connect the shared operational amplifier to a respective portion of a switched-capacitor amplifier circuit corresponding to a respective one of the plurality of channels in response to an asserted one of the plurality of non-overlapping clock signals and further responsive to a reset signal to both short the inputs together and short the outputs together of the shared operational amplifier between assertion of each of the plurality of non-overlapping clock signals and open all switches in the multi-channel switched-capacitor circuit,

14. The amplifier of claim 13, wherein the multi-channel switched-capacitor circuit inhibits sampling or amplifying in any of the plurality of channels when the reset signal is asserted.

15. The amplifier of claim 13, wherein the shared operational amplifier amplifies through the one of the plurality of channels when electrically connected to the respective portion of the switched-capacitor amplifier.

16. The amplifier of claim 15, wherein the shared operational amplifier samples through others of the plurality of channels when electrically connected to the respective portion of the switched-capacitor amplifier.

17. An imager, comprising:
a pixel array; and
a readout circuit selectively coupled to the pixel array, including a multi-channel amplifier, comprising:
a shared operational amplifier including a pair of inputs and a pair of outputs; and
first channel circuitry and second channel circuitry for selectively electrically coupling to the shared operational amplifier in response to first and second non-overlapping clock signals, the first and second channel circuitry further responsive to a reset signal active between assertion of the first and second non-overlapping clock signals to both short the inputs together and the outputs together on the shared operational amplifier and electrically isolate the shared operational amplifier from the first and second channel circuitry.

18. The imager of claim 17, wherein the first and second channel circuitry are configured as switched-capacitor circuits.

19. The imager of claim 18, wherein electrically isolating the shared operational amplifier from the first and second channel circuitry comprises opening all switches in the first and second channel circuitry.

20. The imager of claim 17, further comprising a clock generator to generate the first and second non-overlapping clock signals and the reset signal.

21. The imager of claim 17, wherein the multi-channel amplifier is configured for alternatingly sampling and amplifying in each channel.

22. The imager of claim 21, wherein the reset signal inhibits the sampling and amplifying in any channel when asserted.

23. An imager including a multi-channel readout circuit, comprising:
even and odd channels for reading out image data from even and odd portions of a pixel array;
a shared operational amplifier for alternatingly electrically coupling with each of the even and odd channels to alternatingly perform sampling and amplifying in each of the even and odd channels in response to first and second non-overlapping clock signals; and
in response to a reset signal, the even and odd channels electrically isolate the shared operational amplifier from either of the even and odd channels while shorting the inputs and the outputs together.

24. A system, comprising:
a processor; and
an imaging device, including:
a pixel array; and
a readout circuit selectively coupled to the pixel array, including a shared operational amplifier including a pair of inputs and a pair of outputs and first channel circuitry and second channel circuitry for selectively electrically coupling with the shared operational amplifier in response to first and second non-overlapping clock signals, the first and second channel circuitry further responsive to a reset signal active between assertion of the first and second non-overlapping clock signals to both short the inputs together and the outputs together on the shared operational amplifier and electrically isolate the shared operational amplifier from the first and second channel circuitry.
